(19) United States
(12) Patent Application Publication
(10) Pub. No.: US 2025/0385104 A1
(43) Pub. Date: Dec. 18, 2025

(54) PRODUCTION METHOD FOR SEMICONDUCTOR PACKAGES

(71) Applicant: RESONAC CORPORATION, Minato-ku, Tokyo (JP)

(72) Inventors: Hirokazu NOMA, Chiyoda-ku, Tokyo (JP); Tomohiro HAYASHI, Chiyoda-ku, Tokyo (JP); Yuma TAKEUCHI, Chiyoda-ku, Tokyo (JP); Kasumi NAKAMURA, Chiyoda-ku, Tokyo (JP)

(21) Appl. No.: 18/727,697

(22) PCT Filed: Jan. 13, 2022
(86) PCT No.: PCT/JP2022/000938

§ 371 Date: Jul. 10, 2024

(51) Int. Cl. H01L 21/56; C09J 5/00

(52) U.S. Cl. CPC H01L 21/56; C09J 5/00; C09J 2203/326; C09J 2301/416; C09J 2301/502

(57) ABSTRACT

A production method for semiconductor packages according to the present disclosure includes: adhering an adhesive material to a surface of a first sealing material, peeling off the adhesive material from the surface of the first sealing material, and providing a second member to the surface of the first sealing material from which the adhesive material was peeled off.

### TECHNICAL FIELD

The present disclosure relates to a production method for semiconductor packages.

### BACKGROUND ART

Silicon, which is a main material constituting a semiconductor chip, has a characteristic of being brittle and easily cracked. Therefore, when a semiconductor chip is mounted, the semiconductor chip may be sealed with a sealing material to form a semiconductor package for the purpose of protecting a surface of the semiconductor chip. As a protection method, Five-side protection, Six-side protection, and the like are known.

The Five-side protection is a method for protecting a total of five surfaces of side surfaces of four sides and a terminal surface of the semiconductor chip with a sealing material (Non-Patent Literature 1), and the Six-side protection is a method for protecting a chip back surface with a sealing material in addition to the five surfaces (Non-Patent Literature 2).

The above-described Six-side protection may include a step in which another sealing material is provided to the surface of the sealing material molded on the surface of the semiconductor chip.

In recent years, by providing another semiconductor package on the surface of the semiconductor package, a mounting area is reduced and performance of a system is improved, and such a structure is called a Package on Package (Non-Patent Literature 3).

As a modification of the Package on Package, a structure called Active Mold Packaging in which sealing materials constituting a plurality of semiconductor packages vertically overlap each other is known (Non-Patent Literature 4).

In structures such as the Six-side protection and the Active Mold Packaging, another sealing material is provided to the surface of the sealing material, but excellent adhesiveness is required between these sealing materials.

When heat generation in the semiconductor chip is remarkable, a heat sink is used. Usually, the heat sink is bonded to the surface of the semiconductor chip using an adhesive. The adhesive may be applied not only to the surface of the semiconductor chip but also to the surface of the sealing material, and the sealing material and the heat sink are required to have excellent adhesiveness (Non-Patent Literature 5).

### CITATION LIST

### Non-Patent Literature

Non-Patent Literature 1: T. Tang et al., “Challenges of Ultra-Thin 5 Sides Molded WLCSP,” 2016 IEEE 66th Electronic Components and Technology Conference (ECTC), pp. 1167-1171, 2016.
Non-Patent Literature 2: F. Qin et al., “Study of Warpage Evolution and Control for Six-Side Molded WLCSP in Different Packaging Processes,” IEEE Transactions on Components, Packaging and Manufacturing Technology, vol. 10, no. 4, pp. 730-738, 2020.
Non-Patent Literature 3: S. C. Chong et al., “Development of Package-on-Package Using Embedded Wafer-Level Package Approach,” IEEE Transactions on Components, Packaging and Manufacturing Technology, vol. 3, no. 10, pp. 1654-1662, 2013.
Non-Patent Literature 4: https://www.lpkf.com/en/industries-technologies/active-mold-packaging/amp-technology
Non-Patent Literature 5: Sasanka L. Kanuparthi et al., “Impact of Heatsink Attach Loading on FCBGA Package Thermal Performance,” Proceedings of InterSociety Conference on Thermal and Thermomechanical Phenomena in Electronic Systems, pp. 216-223, 2012.

### SUMMARY OF INVENTION

### Technical Problem

An sealing material can be produced by molding a curable resin composition using molding such as compression molding or transfer molding, but a wax component is added to the curable resin composition in order to secure releasability from a release film, a mold, or the like.

The present inventors have recently found a new problem that when a second member such as a second sealing material or a heat sink is provided to a surface of a first sealing material, a wax component bled out to the surface of the first sealing material adversely affects adhesiveness between the first sealing material and the second member, and may cause peeling at an interface between the first sealing material and the second member in a subsequent heating step such as reflow, a long-term reliability evaluation step, or the like.

The disclosure has been made in view of the problems, and an object of the disclosure is to provide a production method for semiconductor packages excellent in adhesiveness between the first sealing material and the second member.

### Solution to Problem

<1> A production method for a semiconductor package, the method including:
adhering an adhesive material to a surface of a first sealing material;
peeling off the adhesive material from the surface of the first sealing material; and
providing a second member to the surface of the first sealing material from which the adhesive material was peeled off.

<2> The production method for a semiconductor package according to <1>, in which
the second member is a second sealing material, and
the providing the second member to the surface of the first sealing material from which the adhesive material was peeled off is performed by molding a curable resin composition on the surface of the first sealing material.

<3> The production method for a semiconductor package according to <1> or <2>, in which
the adhesive material is a UV peelable adhesive material, and
the production method further including:
irradiating the adhesive material with ultraviolet rays before the adhesive material is peeled off from the surface of the first sealing material.

<4> The production method for a semiconductor package according to any one of <1> to <3>, in which
the second member is a second sealing material, and
the production method further including:
adhering an adhesive material to a surface of the second sealing material;
peeling off the adhesive material from the surface of the second sealing material; and
providing a member that is different from the first sealing material and the second sealing material to the surface of the second sealing material from which the adhesive material was peeled off.

### Advantageous Effects of Invention

According to the production method for a semiconductor package of the disclosure, it is possible to produce a semiconductor package excellent in adhesiveness between a first sealing material and a second member.

### BRIEF DESCRIPTION OF DRAWINGS

FIG. 1 is a schematic cross-sectional view illustrating an embodiment of a semiconductor package produced by producing a semiconductor package of the disclosure.

FIG. 2 is a schematic cross-sectional view illustrating the embodiment of the semiconductor package produced by producing the semiconductor package of the disclosure.

FIG. 3 is a schematic cross-sectional view illustrating the embodiment of the semiconductor package produced by producing the semiconductor package of the disclosure.

### DESCRIPTION OF EMBODIMENTS

Hereinafter, a mode for carrying out the disclosure will be described in detail. However, the disclosure is not limited to the following embodiment. In the following embodiment, the components (including element steps and the like) are not essential unless otherwise stated. The same applies to numerical values and ranges thereof, and the disclosure is not limited thereto.

In the disclosure, a numerical range indicated using “to” includes numerical values described before and after “to” as a minimum value and a maximum value, respectively.

In the numerical ranges described in stages in the disclosure, the upper limit value or the lower limit value described in one numerical range may be replaced with the upper limit value or the lower limit value of the numerical range described in another stage. In the numerical range described in the disclosure, the upper limit value or the lower limit value of the numerical range may be replaced with a value shown in the synthesis example.

In the disclosure, each component may contain a plurality of kinds of corresponding compounds. When a plurality of substances corresponding to each component are present in the composition, a content rate or a content of each component means a total content rate or content of the plurality of kinds of substances present in the composition unless otherwise specified.

In the disclosure, a plurality of kinds of particles corresponding to each component may be included. When there are a plurality of kinds of particles corresponding to each component in the composition, a particle diameter of each component means a value for a mixture of the plurality of kinds of particles present in the composition unless otherwise specified.

In the disclosure, the term “step” includes not only a step independent of other steps but also a step that cannot be clearly distinguished from other steps as long as the purpose of the step is achieved.

In the disclosure, the term “UV peelable adhesive material” refers to an adhesive material in which adhesion or adhesion strength from an adherend such as a first sealing material is reduced by irradiation with UV.

In the disclosure, the term “(meth) acrylic” means at least one of acrylic and methacrylic.

When the embodiment is described with reference to the drawings in the disclosure, the configuration of the embodiment is not limited to the configuration illustrated in the drawings. Sizes of members in each drawing are conceptual, and a relative relationship between the sizes of the members is not limited thereto.

### [Production Method for Semiconductor Packages]

A production method for a semiconductor package of the disclosure includes the steps of: adhering an adhesive material to a surface of a first sealing material; peeling off the adhesive material from the surface of the first sealing material; and providing a second member to the surface of the first sealing material from which the adhesive material was peeled off.

According to the production method for semiconductor packages of the disclosure, it is possible to provide a semiconductor package excellent in adhesiveness between the first sealing material and the second member. The reason is presumed as follows.

In the production method for semiconductor packages of the disclosure, before the step in which the second member is provided to the surface of the first sealing material, an adhesive material is adhered to the surface of the first sealing material and peeled. It is presumed that the adhering and peeling of the adhesive material remove a wax component bled out to the surface of the first sealing material, so that adhesiveness between the first sealing material and the second member is improved.

The production method for semiconductor packages of the disclosure can remove the wax component bled out to the surface of the first sealing material by a simple method such as adhering and peeling of the adhesive material, and does not require a special device and operation, and thus is excellent in cost, ease of producing, and the like. Hereinafter, each step that can be included in the production method for semiconductor packages of the disclosure will be described.

(Step in which Pasting Adhesive Material is Pasted to Surface of First Sealing Material)

The production method for semiconductor packages of the disclosure includes adhering an adhesive material to a surface of a first sealing material. The adhering of the adhesive material may be performed on one surface of the first sealing material, may be performed on two or more surfaces, may be performed on a part of the surface, or may be performed on the entire surface, but is preferably performed on at least a portion where the second member is provided.

The adhesive material can be used without particular limitation as long as it can be adhered to the first sealing material and can be peeled. The adhesive material having a tape shape or a sheet shape is excellent in handleability.

From the viewpoint that an adhesive force can be controlled and a wax component can be removed without breaking the first sealing material or the like at the time of peeling, the adhesive material is preferably a UV peelable adhesive material.

As the adhesive material, a detachable sticky paper with a pressure-sensitive adhesive or the like may be used, and it is not necessary to use an ultraviolet irradiation device or the like, which is preferable from the viewpoint of ease of operation.

In one embodiment, the first sealing material is a cured product of a curable resin composition. The curable resin composition can contain one or two or more kinds of thermosetting resins, and examples thereof include an epoxy resin, a (meth)acrylic resin, a phenol resin, a urea resin, a melamine resin, a urethane resin, a silicone resin, and an unsaturated polyester resin.

When the curable resin composition contains a thermosetting resin, a content rate of the thermosetting resin with respect to the mass of the curable resin composition is preferably from 0.5 mass % to 50 mass %, and more preferably from 2 mass % to 30 mass % from the viewpoint of strength, fluidity, heat resistance, moldability, and the like.

The curable resin composition may contain one or two or more kinds of curing agents, and examples thereof include a phenol curing agent, an amine curing agent, an acid anhydride curing agent, a polymercaptan curing agent, a polyaminoamide curing agent, an isocyanate curing agent, a blocked isocyanate curing agent, and the like.

When an epoxy resin is used as the thermosetting resin, an equivalent ratio between the epoxy resin and the curing agent, that is, a ratio of the number of functional groups in the curing agent to the number of functional groups in the epoxy resin (the number of functional groups in the curing agent/the number of functional groups in the epoxy resin) is not particularly limited, but is preferably set to a range of from 0.5 to 2.0 and more preferably set to a range of from 0.6 to 1.3 from the viewpoint of suppressing the unreacted component to a small amount. From the viewpoint of improving the moldability and reflow resistance, it is more preferably set to a range of from 0.8 to 1.2.

The curable resin composition may contain one or two or more kinds of wax components, and examples thereof include higher fatty acids such as carnauba wax, montanic acid, and stearic acid, higher fatty acid metal salts, ester waxes such as montanic acid esters, and polyolefin waxes such as oxidized polyethylene and non-oxidized polyethylene.

When the curable resin composition contains a wax component, the content of the wax component is preferably from 0.01 parts by mass to 15 parts by mass, and more preferably from 0.1 parts by mass to 10 parts by mass, based on 100 parts by mass of the thermosetting resin contained in the curable resin composition, from the viewpoint of improving releasability from a mold at the time of molding the first sealing material.

The curable resin composition may contain a curing accelerator, an inorganic filler (copper, gold, silver, nickel, alloys thereof, spherical silica, crystalline silica, and the like), a coupling agent, an ion exchanger, an antioxidant, an organic solvent, a release agent, a colorant, rubber particles, a leveling agent, an antifoaming agent, and the like.

A semiconductor package produced by the production method for semiconductor packages of the disclosure can include an element sealed with the first sealing material and a substrate on which the element is disposed.

When the semiconductor package includes a sealing material other than the first sealing material such as a second sealing material or a third sealing material described later, the semiconductor package may include an element sealed with a sealing material other than the first sealing material, and a substrate on which the element is disposed.

Examples of the element include an active element such as a semiconductor chip, a transistor, a diode, or a thyristor, and a passive element such as a capacitor, a resistor, or a coil.

Examples of the substrate include a lead frame, a wired tape carrier, a wiring board, glass, a silicon wafer, an organic substrate, and the like. The substrate may have a through-hole for connecting an element included in the first sealing material and an element sealed with a sealing material other than the first sealing material.

The first sealing material and the sealing material other than the first sealing material can be produced by molding a curable resin composition using compression molding, transfer molding, or the like.

In one embodiment, the first sealing material may be provided to a surface of a sealing material (hereinafter, it is also referred to as a sealing material base material) to which a pressure-sensitive adhesive is not adhered or peeled. The first sealing material may be provided to a surface and side surfaces of the sealing material base material, or may be provided to the entire surface. The sealing material base material can be a cured product of the curable resin composition described above. A semiconductor package produced by the production method for semiconductor packages of the disclosure can include an element sealed with a sealing material base material and a substrate on which the element is disposed.

(Step in which Adhesive Material is Peeled from Surface of First Sealing Material)

The production method for semiconductor packages of the disclosure includes peeling off an adhesive material from a surface of a first sealing material. The adhesive material may be peeled manually or by using a peeling device.

At the time of peeling the adhesive material from the first sealing material, a preferable numerical range of peeling strength of the adhesive material varies depending on a composition of the first sealing material, but is preferably from 0.03 N/10 mm to 3.5 N/10 mm, and more preferably from 0.3 N/10 mm to 1.0 N/10 mm from the viewpoint of improving wax removability, a breakage suppressing property of the first sealing material, and the like.

The time from the adhering of the adhesive material to the first sealing material to the peeling is not particularly limited, but can be, for example, from 10 seconds to 24 hours. A pressure may be applied at the time of adhering the adhesive material, and the pressure can be set to from 0.01 MPa to 0.5 MPa.

(Step in which Second Member is Provided to Surface of First Sealing Material from which Adhesive Material was Peeled)

The production method for semiconductor packages according to the disclosure includes providing a second member to a surface of a first sealing material from which an adhesive material was peeled off.

Examples of the second member include a second sealing material, a heat sink, a lid, a stiffener, an electromagnetic shield, an adhesive layer formed of an adhesive, and the like.

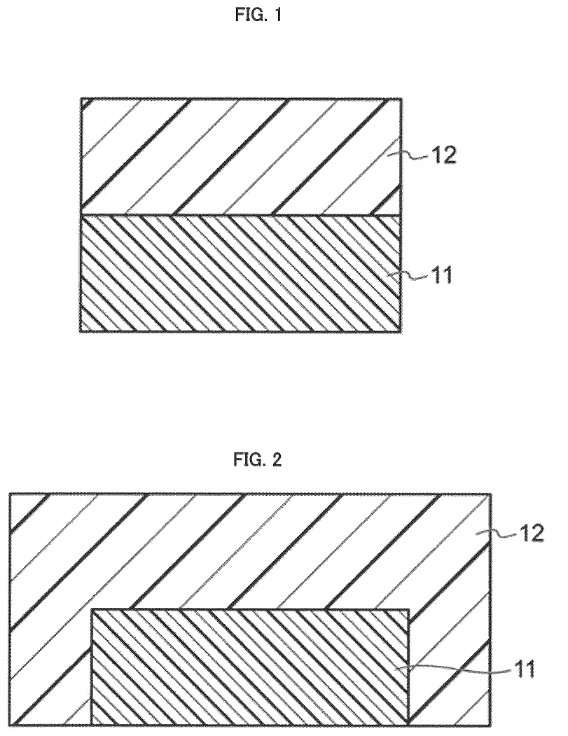

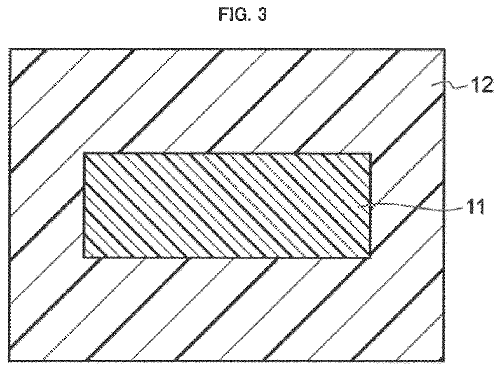

When the second member is a second sealing material, a second sealing material 12 may be provided only to the surface of a first sealing material 11 from which the adhesive material was peeled (see FIG. 1), may be provided to the surface of the first sealing material 11 from which the adhesive material was peeled and the four side surfaces of the first sealing material 11 (see FIG. 2), or may be provided to the entire surface of the first sealing material 11 (see FIG. 3). The various kinds of second sealing materials can be produced by changing a mold to be used.

When the second member is a second sealing material, the second sealing material can be provided to the surface of the first sealing material by molding the curable resin composition on the surface of the first sealing material.

As the curable resin composition, those described above can be used, and the curable resin compositions constituting the first sealing material and the second sealing material may be the same or different, but are preferably the same from the viewpoint of improving adhesiveness between the sealing materials.

When the second member is a second sealing material, the second sealing material can be provided to the surface of the first sealing material by bonding the second sealing material produced by molding the curable resin composition to the first sealing material using a conventionally known adhesive.

When the second member is a heat sink, a lid, a stiffener, or an electromagnetic shield, the heat sink or the like can be provided to the surface of the first sealing material by bonding the heat sink or the like to the first sealing material using a conventionally known adhesive.

When the second member is a second sealing material, the production method for a semiconductor package of the disclosure can further include the steps of: adhering an adhesive material to the surface of the second sealing material, peeling off the adhesive material from the surface of the second sealing material, and providing a third member to the surface of the second sealing material from which the adhesive material was peeled.

The semiconductor package produced by the production method for semiconductor packages including the steps is excellent in adhesiveness between the second sealing material and the third member.

The details of the adhesive material, the adhering surface, and the like used in the step in which the adhesive material is adhered to the surface of the second sealing material and the step in which the adhesive material is peeled from the surface of the second sealing material are the same as those of the adhering and peeling of the adhesive material with respect to the first sealing material, and the description thereof is omitted here.

Examples of the third member include a third sealing material, a heat sink, a lid, a stiffener, an electromagnetic shield, and the like.

The details of the step in which the third member is provided are similar to those of the step in which the second member is provided, and thus the description thereof is omitted here.

When the third member is a third sealing material, as the curable resin composition constituting the third sealing material, those described above can be used, and the curable resin compositions constituting the first sealing material, the second sealing material, and the third sealing material may be the same or different.

A semiconductor package may be produced by repeatedly performing the steps such as a fourth sealing material on the surface of the third sealing material and a fifth sealing material on the surface of the fourth sealing material.

(Step in which Adhesive Material is Irradiated with Ultraviolet Rays)

When a UV peelable adhesive material is used as the adhesive material, the production method for semiconductor packages of the disclosure can include a step in which the adhesive material is irradiated with ultraviolet rays before the step in which the adhesive material is peeled from the surface of the first sealing material.

When the second member is a second sealing material, and the production method for semiconductor packages of the disclosure further includes a step in which an adhesive material is adhered to a surface of the second sealing material, a step in which the adhesive material is peeled from the surface of the second sealing material, and a step in which a third member is provided to the surface of the second sealing material from which the adhesive material was peeled, and the UV peelable adhesive material is used as the adhesive material, the production method for semiconductor packages of the disclosure may include a step in which the adhesive material is irradiated with ultraviolet rays before the step in which the adhesive material is peeled from the surface of the second sealing material.

Since the adhesive force of the adhesive material to the first sealing material and the second sealing material can be reduced by irradiation with ultraviolet rays, it is possible to remove the wax component and to suppress breakage or the like of the first sealing material and the second sealing material.

A UV irradiation device is not particularly limited, and examples thereof include a high-pressure mercury lamp, a xenon lamp, a metal halide lamp, an LED, and the like.

The wavelength of UV to be irradiated is not particularly limited, but may be from 365 nm to 405 nm. The irradiation energy is not particularly limited, but may be from 100 mJ/cm² to 2,000 mJ/cm².

(Step in which Semiconductor Package is Diced)

The producing of the semiconductor package of the disclosure may include a step in which the semiconductor package produced through the steps is diced. The size of the semiconductor package after dicing is not particularly limited, and is preferably appropriately changed according to the application of the semiconductor package.

### EXAMPLES

Hereinafter, an embodiment of the disclosure will be described more specifically with reference to Examples. However, the disclosure is not limited to these Examples.

### Example 1

An sealing material base material having a width of 75 mm×a length of 240 mm× a thickness of 0.5 mm was molded by compression molding. A wax component-containing epoxy resin composition as a curable resin composition was used for the production of the sealing material base material.

A first sealing material having a diameter of 296 mm× a thickness of 0.5 mm (excluding a thickness of a base material) was provided to a surface and side surfaces of the sealing material base material.

The first sealing material was molded by compression molding using a resin composition used for molding the sealing material base material.

A UV peelable dicing tape was adhered to one surface of the first sealing material, and allowed to stand in an environment of 23° C. and a relative humidity of 50% for one hour.

After the standing, the dicing tape was irradiated with UV, and the dicing tape was peeled from the first sealing material to obtain a semiconductor package.

### Comparative Example 1

A semiconductor package was produced in the same manner as in Example 1 except that no dicing tape was adhered to the first sealing material and the second sealing material.

### <<Evaluation of Adhesiveness>>

A pin (produced by Quad Group, Inc.) for a stud pull test to which an adhesive was applied was bonded to the surface of the first sealing material of the semiconductor package produced in each of the Example and Comparative Example, from which the dicing tape was peeled. An adhesive layer as a second member was formed between the first sealing material and the pin by the adhesive.

The semiconductor package to which the pin was bonded was set in a stud pull tester (ROMULUS manufactured by Quad Group), the pin was pulled in a vertical direction, a maximum value of the adhesive force was measured, and the results are summarized in Table 1.

After the measurement of the adhesive force, the semiconductor package was visually confirmed. As a result, in the semiconductor package of Example 1, the first sealing material was cohesive fractured, but peeling did not occur at the interface between the first sealing material and the adhesive layer as the second member.

In the semiconductor package of Comparative Example 1, peeling occurred at the interface between the first sealing material and the adhesive layer as the second member.

TABLE 1

| | Example 1 | Comparative Example 1 |
|---|---|---|
| Adhesive force | 49 | 32 |
| (MPa) | | |
| Peeling form | Cohesive fracture of | Peeling in interface between first |
| | first sealing material | sealing material and adhesive |
| | | layer as second member |

Table 1 shows that the semiconductor package produced by the production method for semiconductor packages of Example 1 in which the dicing tape was adhered and peeled with respect to the first sealing material before the adhesive layer as the second member was formed is excellent in adhesiveness between the first sealing material and the second member.

### DESCRIPTION OF REFERENCE NUMERALS

11 First sealing material
12 Second sealing material.

1. A production method for a semiconductor package, the method comprising:
adhering an adhesive material to a surface of a first sealing material;
peeling off the adhesive material from the surface of the first sealing material; and
providing a second member to the surface of the first sealing material from which the adhesive material was peeled off.

2. The production method for a semiconductor package according to claim 1, wherein
the second member is a second sealing material, and
the providing the second member to the surface of the first sealing material from which the adhesive material was peeled off is performed by molding a curable resin composition on the surface of the first sealing material.

3. The production method for a semiconductor package according to claim 1, wherein
the adhesive material is a UV peelable adhesive material, and
the production method further comprising:
irradiating the adhesive material with ultraviolet rays before the adhesive material is peeled off from the surface of the first sealing material.

4. The production method for a semiconductor package according to claim 1, wherein
the second member is a second sealing material, and
the production method further comprising:
adhering an adhesive material to a surface of the second sealing material;
peeling off the adhesive material from the surface of the second sealing material; and
providing a member that is different from the first sealing material and the second sealing material to the surface of the second sealing material from which the adhesive material was peeled off.
